(19) United States
(12) Patent Application Publication
(10) Pub. No.: US 2007/0052557 A1
(43) Pub. Date: Mar. 8, 2007

(54) Shared memory and shared multiplier programmable digital-filter implementation

(76) Inventors: Thomas Magdeburger, Murphy, TX (US); Dennis R. Best, Lucas, TX (US)

Correspondence Address: John A. Thomas, 13355 Noel Road, L.B. 48, Dallas, TX, 75240-1518, US

(21) Appl. No.: 11/219,376

(22) Filed: Sep. 2, 2005

(51) Int. Cl. H03M 7/00

(52) U.S. Cl. 341/50; 708/300

(57) ABSTRACT

An integrated circuit for implementing a digital filter has a data memory; the data memory having two ports to permit the access of two data samples at the same time, and a coefficient memory for storing filter coefficients. A first adder adds data samples from first and second data memory ports; a multiplier multiplies a value from the first adder by a value from the coefficient memory; and, a second adder accumulates values from the multiplier. A master controller is provided configured for selectively storing the accumulated values in the data memory for further processing or outputting the accumulated values. An address and control block communicating with the data memory and the coefficient memory holds values appropriate to the filter to be executed. The address and control block has two sets of a first set of registers for holding values for a first pre-determined digital filter and a second pre-determined digital filter in cascade. The method maintains a current write address for data in the address control block as a circular list, where the circular list has a size equal to a predetermined number of filter taps;. The method maintains a first read address for data from the first port as a first-in-first-out queue, a second read address for data from the second port as a last-in-first-out stack, and a coefficient read address as a circular list.

### CROSS-REFERENCE TO RELATED APPLICATION

The present application is related to U.S. patent application Ser. No. 10/884,200, filed Jul. 6, 2004, and having the title of: “System and method for design and implementation of integrated-circuit digital filters,” which application is incorporated by reference into the present application.

### TECHNICAL FIELD

This disclosure relates to efficient implementation, in power, performance, and physical size, of electronic circuitry to perform digital filtering of electronic signals over a wide, selectable range of frequencies. The implementation can be used to rapidly program and execute a particular Finite Impulse Response (FIR) filter, a cascade of FIR filters, or multi-rate FIR filters to meet an application's frequency selectivity specifications.

### BACKGROUND

The mathematical algorithms for computing a digital FIR filter are well known, and have recently enjoyed widespread use as high computation rate digital hardware has become available. However, most implementations are very specific to a fixed frequency band since the calculations require a high multiply and accumulate rate, and multipliers are expensive—large area or time delay—to implement. Implementations for lower frequency bands are often performed in digital signal processors via software, but higher frequency bands are typically implemented in highly optimized specific hardware and are applicable to a specific set of frequencies, and sometimes for a specific filter (a fixed number of taps) losing the desired attribute of programmability.

The general form of the sampled data equation for implementing a FIR filter is as follows:

$$N - 1$$

$$y ( n ) = Σ b ( i ) x ( n - i )$$

$$i = 0$$

Where: y(n)=filter output for sample time n

b(i)=filter coefficients for filter of order N-1

x(n)=filter input at sample time n

N=number of filter taps

Since linear phase FIR filters have “mirrored image” coefficients about the center coefficient, a folded-coefficients approach can reduce the number of multiplies by a factor of two. For particular filters with a fixed number of taps (fixed order), the equation can readily be implemented by saving the samples in a shift register of length N-1 and providing enough adders and multipliers to complete the computation for each output sample before the arrival of the next input sample. However, if the number of taps is programmable, the addressing of the shift register to accommodate the minimum to maximum number of taps requires more complex hardware. And if the implementation must accommodate a programmable sample frequency rate, the processing rate of the adders, multipliers, and the accumulator must be designed to accommodate the worst case throughput rate (number of taps times the input sample rate). If we also desire to provide for cascaded filters (often used with decimation to reduce the over sampled input rate to II the desired output sample rate) and multi-rate filters (used with decimation in the first filter and interpolation in the second filter to effectively perform very high number of taps filters with a greatly reduced number of multiplies), then the logic and registers increases even more, and the power requirements do not scale linearly with sample frequency.

### SUMMARY

We disclose an integrated circuit and method for implementing a digital filter The integrated circuit has a data memory; the data memory having first and second ports to permit the access of two data samples at the same time, and a coefficient memory for storing filter coefficients. There is a first adder for adding data samples from the first and second ports addressed in data memory; a multiplier for multiplying a value from the first adder by a value from the coefficient memory; and, a second adder for accumulating values from the multiplier.

A master controller is provided configured for selectively storing the accumulated values in the data memory for further processing or outputting the accumulated values. The integrated circuit further comprises an address and control block for holding values appropriate to the filter to be executed; the address and control block being in communication with the data memory and the coefficient memory.

The address and control block further comprises a first set of registers for holding values for a first pre-determined digital filter, and a second set of registers holding corresponding values for a second pre-determined digital filter. The first set of registers has at least: a write address register holding the address of the next input data to, selectively, data memory, or coefficient memory; a first read address register holding the address of the next data memory address to be read from the first port; a second read address register holding the address of the next data memory address to be read from the second port; and, a coefficient address register holding the address of the next coefficient to be read.

The method of implementing the filter in the preferred embodiment comprises maintaining a current write address for data in the address control block as a circular list, where the circular list has a size equal to a predetermined number of filter taps. The method maintains a first read address for data from the first port as a first-in-first-out queue, a second read address for data from the second port as a last-in-first-out stack, and a coefficient read address as a circular list. The coefficient address has a size equal to the pre-determined number of filter taps divided by 2 and rounded up if the number of filter taps is odd. The method further comprises storing an input digital sample in the data memory, at a location determined by a current write address in the address control block; computing an output sample for the first digital filter from the stored samples in the data memory and the stored coefficients in the coefficient memory; exchanging the first set of parameters in the address control block with the second set of parameters in the address control block; and computing an output sample for the cascaded digital filter from the stored samples in the data memory and the stored coefficients in the coefficient memory. After computation, the first set of parameters in the address control block is exchanged with the second set of parameters in the address control block, where a second filter is to be computed.

### DRAWINGS

FIG. 1 shows the overall block diagram of the preferred embodiment.

FIG. 2 is a flow chart showing the flow of execution in the master controller function of the preferred embodiment.

FIG. 3 is a flow chart showing the flow of execution in the address control function of master controller.

### DESCRIPTION

This disclosure describes an implementation of a hardware set that is programmable over a wide frequency range, with the range being limited only by the performance of the multiplier or the access times of memories or registers used to store data and coefficients. The design also accommodates linear filters of from 3 to N taps, where N is limited only by the memory size and compute rate that is practical with current IC technology constraints. The same hardware resources may be used to perform cascaded or multi-rate filters with little additional control hardware.

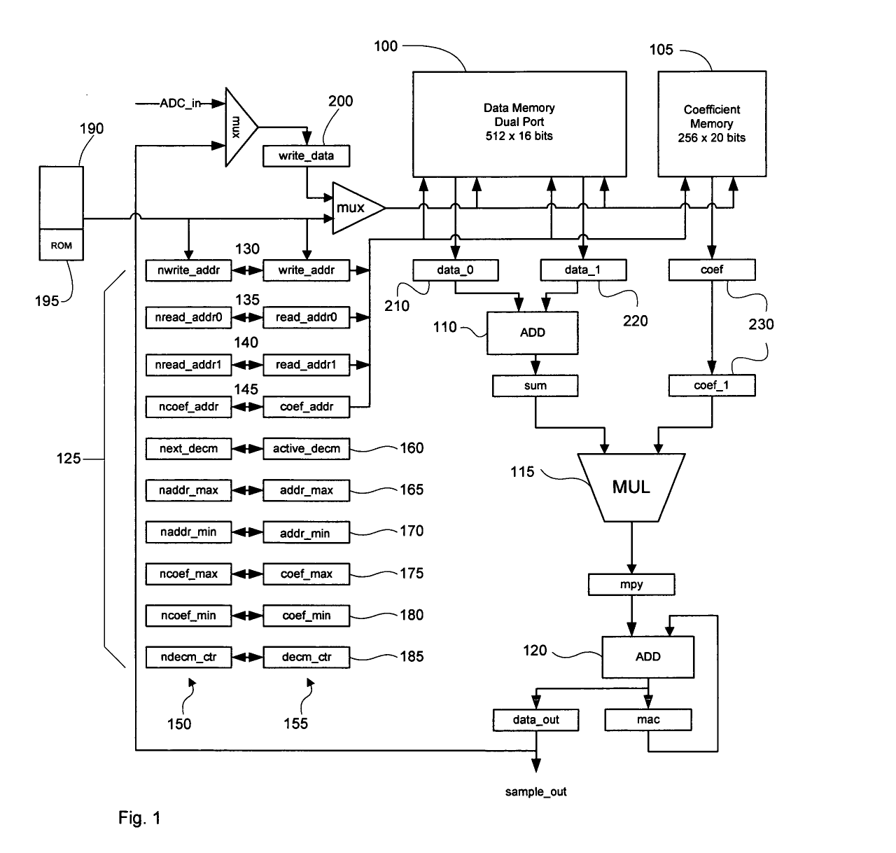

FIG. 1 illustrates the overall block diagram of the preferred embodiment. The data memory (100) is used to store input samples, typically from an analog input that has been anti-alias filtered and digitized by an analog-to-digital converter. The data memory (100) is also used to store computed output samples from a first filter operation for use by a second filter operation when the system is programmed for cascade or multi-rate filtering. The memory (100) is preferably organized as a two-port memory to permit the access of two samples at a time, with one port being a read only port and the other being a read or write port.

The coefficient memory (105) holds the coefficients, or tap weights, for one or more filters. The coefficient memory (105) is sized to hold a number of unique coefficients for the one or more filters to be executed. The number of coefficients is one-half the number of taps for folded-filter designs.

Both the data (100) and the coefficient (105) memories are preferably random-access memory (RAM).

The add, multiply, and accumulate (AMAC) functions are used to perform the basic arithmetic functions of the FIR operation. The AMAC functions include the first adder (110), the multiplier (115), and the accumulate function (120). Note that, in the preferred embodiment, the accumulated results are stored in the data memory (100) or output for further processing. The AMAC functions are controlled by the values stored in the address and control block (125). The master controller (190) loads the coefficients from the program input into the coefficient memory (105), and stores other control parameters necessary to execute the desired filter functions. These parameters include the number of taps for each filter, the initial starting and ending addresses for each filter's samples and coefficients, and the decimation and interpolation values for each filter.

FIG. 1 shows the set of next-filter address and control registers (150) and the set of active-filter address and control registers (155), constituting together the address-and-control-block registers (125). The master controller (190) is a processor that has associated with it a computer-readable medium (195) The computer-readable medium could be a read-only memory (ROM), a flash memory, or a RAM into which the program for the master controller (190) has been previously loaded. The ROM (195) (so designated in FIG. 1) holds a stored program for executing the instructions necessary to implement digital filters as described in this disclosure.

For a folded FIR operation, the AMAC functions receive two operands from the data memory (100), sums these operands in the first adder (110), multiplies this result in the multiplier (115) by the coefficient selected from the coefficient memory (105), and accumulates this result in the accumulator (120). If the accumulated value is the result of the operation of a single FIR filter, or the second filter of cascaded filters, the result is output to a post-processor (not shown); if the value is the result of the first filter of cascaded filters, the result is stored in the data memory space reserved for inputs to the second filter operation.

The address and control block registers (125) and the coefficient memory (105) are pre-loaded by a master controller (190) with the values appropriate for the filter to be executed. In the preferred embodiment, the values loaded are in turn pre-loaded by the master controller (190) from a source external to the filter hardware, such as by a serial port connected to an external processor. For an example of such a method and apparatus for pre-loading filter parameters, see the referenced co-pending application, Ser. No. 10/884,200. This disclosure, however, is not limited by the system and methods disclosed in that co-pending application.

The master controller (190) starts executing the filter operations by developing all addresses, gating functions, and timing required to capture an input sample; performing the generalized FIR equation to develop an output sample; outputting the sample (or storing the sample in data memory (100) for use by a second filter; and switching control from the first to the second filter operation (if cascaded filters are implemented) at the appropriate time. Note that if decimation is enabled, only one of n output samples is computed, where n is the decimation value.

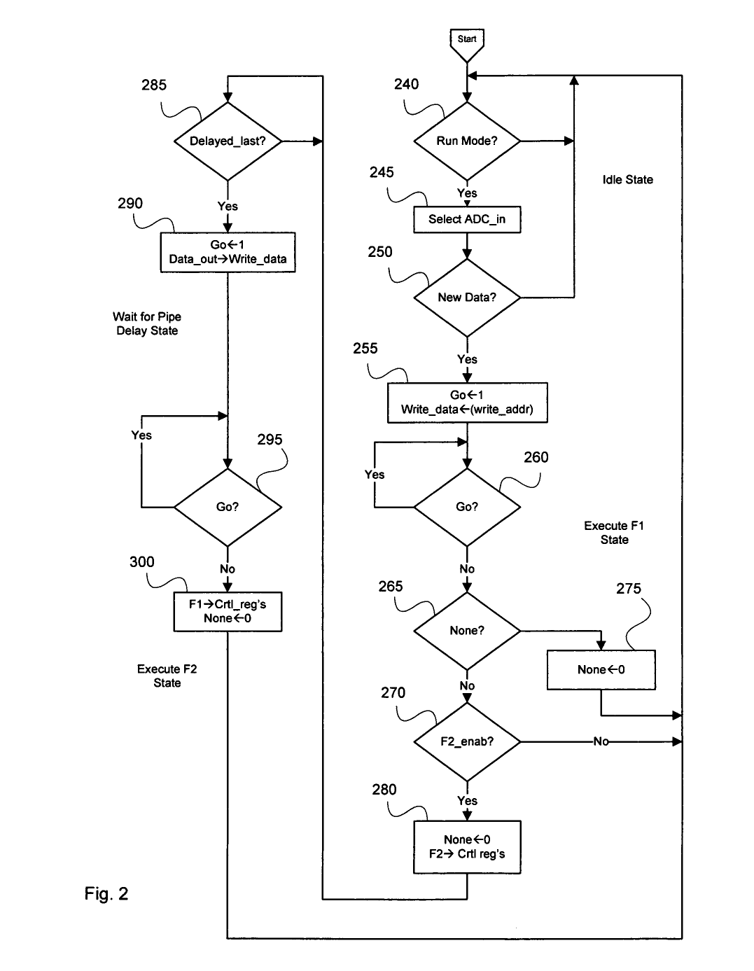

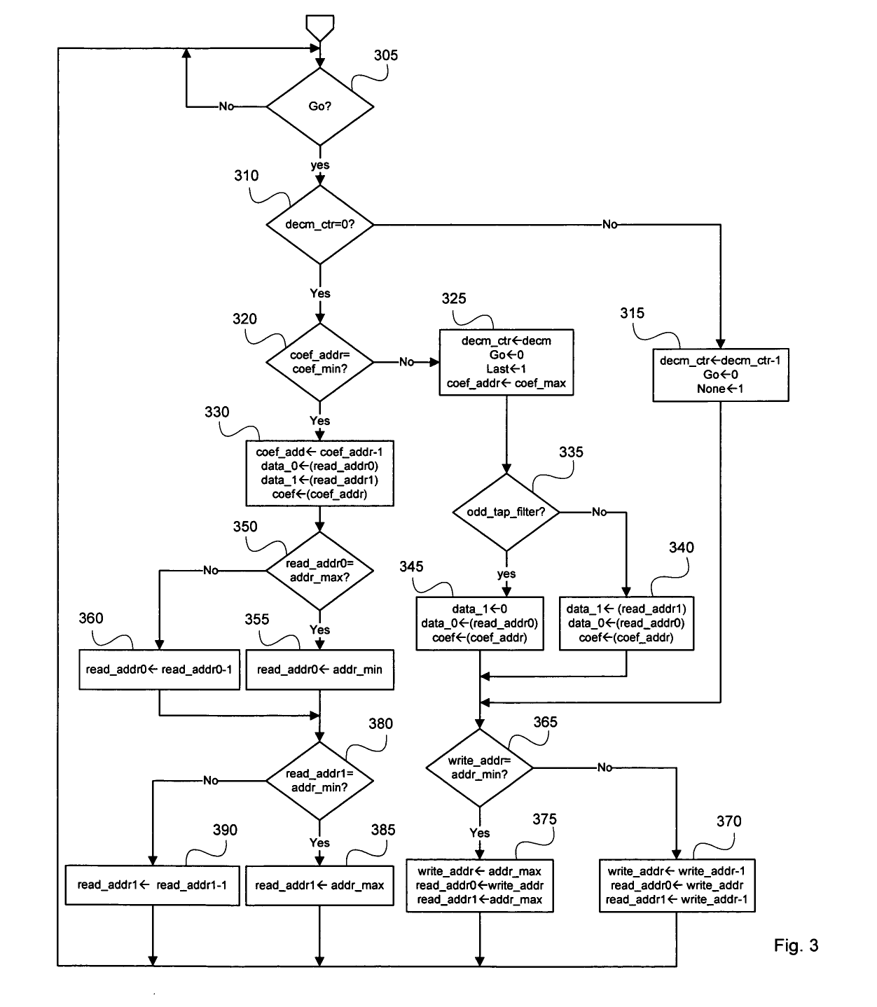

The FIR design of the preferred embodiment is based on the folded approach to execution to reduce the number of multiplies. Since the number of taps may be very large, a shift register implementation is not realistic, therefore we must maintain the data points in memory, and present the data elements to the AMAC hardware, along with the coefficients, in the correct order. We do this by addressing the elements in a circular shift fashion over the prescribed number of taps of the filter, repeating the process as new data elements are entered into the array of data (with the starting addresses appropriately shifted as we overwrite the oldest data point with the newest data point), as shown in FIGS. 2 and 3, discussed below.

This design uses a single set of AMAC functions and a dual-port, 16 bit data memory (100). FIG. 1 shows the two data port, marked data_0 for the first port (210) and data_1 for the second port (220). In the preferred embodiment the coefficients will be stored in a separate memory (105) that is 20 bits wide. The reader will see that longer or shorter words could be used for the data or the coefficients in other implementations.

The master controller (190) or a similar computer means will control the writing of new data into the assigned memory space, and start the computation of a new data point. This controller will also swap the appropriate starting addresses into the address registers to permit cascaded filters with or without decimation for each filter.

### Memory Allocation

The data memory (100) for each filter will be assigned the virtual address space zero to N-1, where N is the number of taps. The dual-port memory has first (210) and second (220) ports; one read and write port and one read-only port. To accommodate multiple filters, the actual address space will be offset from zero. The coefficient memory (105) assigned will be N/2 20 bit words in the preferred embodiment, rounded up for N not divisible by 2. The starting address for storing new data in data memory (100) will be N-1 plus the appropriate offset, and the write address register will count down until it reaches virtual address zero, and then will be reloaded with virtual address N-1. The first filter data space will range from address 0 to N₁−1, and the second filter space will start at N₁ and end at N₁+N₂−1. Coefficients will be stored with coefficient zero in the upper address space with the coefficient address decreasing for higher order coefficients. The upper coefficient will be in coefficient virtual address zero.

### Memory Addressing

The write address register (130) (write_addr) contains the address for storing the next input operand to the virtual memory space. It will be updated at the completion of the data output calculation.

The coefficient address register (145) (coef_addr) contains the address of the next coefficient to be accessed from the coefficient memory (105) data port (230). It is updated each clock cycle. The boxes marked coef and coef_1 for the coefficient memory (105) data port (230) indicate that a second buffer is preferably used for this port (230) to maintain timing of the data flow of operands to the multiplier (115).

The operand address registers, read_addr0 (135) and read_addr1 (140), contain the addresses of the two operands to be accessed each clock from respectively, the first data port (210) and the second data port (220), read_addr0 being the address for reading data from the first data port (210), and read_addr1 being the address for reading data from the second data port (220).

Constant registers include the maximum and minimum addresses for the paired data operands and the coefficients: addr_max (165), addr_min (170), and coef_max (175) and coef_min (180), respectively. These values are used to compare to the address registers to ‘wrap’ the address values over the operand address ranges and provide initial addresses at the completion of data point calculations.

Down sampling is controlled by a decrement counter (185) (decm_ctr) that is preloaded to zero, and a constant register (160) (decm). Data points are computed only for the inputs for which the decrement counter (185) is equal to zero. Other inputs are stored, but not computed (i.e., there is no output data point) and the address counters are updated. For example, a filter with a decimation value of four would compute an output sample only for every four input samples.

The control of addresses for each data point calculation essentially treats the input data as stacks with read_addr0 registers (135) operating as a FIFO queue starting with the newest data word to be read from the first port (210) and the read_addr1 registers (140) operating as a LIFO stack, starting with the oldest data word to be read from the second port. After the completion of an execution cycle, the next data input replaces the oldest data point in memory, the stack addresses are shifted appropriately and execution of the next output begins.

### Control Operations

The control of the address registers is illustrated by the simplified flowcharts in FIGS. 2 and 3. FIG. 2 illustrates the program running in the master controller (190) and FIG. 3 shows the operation of the address controller functions of the master controller (190).

The master controller (190) separately maintains the state control for each filter. This control includes a pointer to the address to store the next input sample, the number of coefficients, and the starting address for the coefficient set. Upon receiving an input, the master controller (190) stores the input at the sample pointer address, addresses the coefficients and samples to be used in the add, multiply, and accumulate logic, and outputs the computed sample. If decimation is used, the master controller (190) will store the input, but only compute and output 1 out of n inputs, where n is the decimation value. The master controller (190) then increments the input pointer address, and switches context to the state of the second filter operation, and then performs the same functions for the second filter. (Note that if interpolation is enabled, the master controller (190) inserts zeros for m of m+1 outputs passed from the first to the second filter for multi-rate filters.) At the completion of the second filter's operations, the master controller (190) updates the second filter's pointers and switches state back to the first filter, and the process continues, as described below and in the flowcharts of FIGS. 2 and 3.

The registers in the address and control block (125) are pre-loaded with the appropriate values for a filter or a pair of filters. At step 240, the program checks to see if Run Mode is set. If so, the program selects input from the analog-to-digital converter at step 245. The program checks for New Data (a new input sample) at step 250. The master controller (190) remains in the idle state until receiving an input sample into the write_data register (200) as indicated by the New Data signal. The master controller (190) then sets a Go signal to the address controller function at step 255 to initiate processing of the first filter's output sample, and writes the first sample to the data memory (100). The program then enters the Execute-F1 state at step 260 to await completion of output sample processing (where “F1” refers to the first of two cascaded filters). The address controller signals completion of sample processing by resetting the Go signal at step 315 or step 325. Note that if the program is in this state, and no sample is to be computed, (the decrement counter (180) is non-zero), the master controller (190) returns to the idle state at step 275, as it does if there is only one filter enabled. The None signal is set by the address controller function at 245 to indicate that no sample has been computed. If there is a second filter, the control registers for the second filter are moved to the active registers at step 280.

If a second filter sample is to be computed, the program enters a wait state at step 285 to await the delayed Last signal indicating that the sample result has completed processing in the AMAC pipeline. The sample result value is then written to data memory (100) at step 290 and Go is set to start sample processing as the controller enters the Execute-F2 state (where “F2” refers to the second of two cascaded filters) at step 300, moving the F2 values to the control registers and setting None to zero. The address controller function indicates completion of the F2 output sample by resetting Go.

As shown in FIG. 3, the address controller function performs all address calculations for memory addressing and transfers to operand registers feeding the AMAC functions. If a Go signal is present at step 305, the address-controller function checks the decimation counter value (185) at step 310.

If the decimation value is non-zero at step 310, the program decrements the decimation counter and sets Go to zero and None to true at step 315; else the program next checks the coefficient address at step 320 to determine if it as at the minimum II address. If it is not, the decimation counter is loaded with the decimation constant (160) at step 325, Go is set to zero, the Last flag is set true and the coefficient address value (145) is set to the maximum value in the constant register (175). If the coefficient address is at its minimum value, then, at step 330, the program decrements the coefficient address, moves the data in data memory (100) at the read-address values in the read_addr registers (135, 140) to the data registers for the first adder, and moves the coefficient value at the current coefficient address to the coefficient register (coef_1) associated with the multiplier (115).

If the coefficient address was at its minimum value, then, after step 325, the program checks for an odd-tap filter at step 335. If there is none, then, at step 340, data is loaded from data memory (100) at the current read addresses, as well as the coefficient data. If there is an odd-tap filter, then at step 345, the data register associated with the first port (210) (data_0) is set to the value pointed to by the read_addr0 (135) value, the register associated with the second port (220) (data_1) is set to zero, and the register associated with the coefficient memory port (230) (coef) is loaded from the current coefficient address. Execution from step 345 proceeds to step 365 where the write address is checked for its minimum value. If the value is at a minimum, the write address register (130) is set to the maximum address from the addr_max constant register (165), the read_addr0 register (135) is set to the write address, and the read_addr1 (140) is set to the maximum address. If the write address is not at its minimum, then step 370 decrements the write address register (130), moves the write address to the read_addr0 register (135) and moves the decremented write address to the read_addr1 register (140). Execution then returns to step 300.

Continuing from step 330, the program checks at step 350 to determine if the value in the read_addr0 register (135) is at its maximum. If not, the read address is decremented at step 360, and execution passes to step 380. Else, the constant in the addr_min register (170) is loaded into the read_addr0 register (135), and execution passes to step 380.

Step 380 checks to determine if the value in the read_addr1 register (140) is at the minimum address in constant register addr_min (170). If not, the read address is decremented; else, the read_addr1 register (140) is set to the value in the addr_max constant register (165) and execution passes to step 300.

As just described, then, the address controller function also handles the wrap-around of the FIFO and LIFO addressing for folded FIR operation. It indicates completion of the calculation by resetting Go.

Note also that the operand address registers are 9 bits to address the 512×16 bits data memories, and the coefficient address registers are 8 bits to address the 256×20 bits coefficient memories. Again, the reader should recognize that these values are merely exemplary, and other implementations could have different-sized words in the memories.

Corresponding to the values listed for the illustrated embodiment, the operands add register is 17 bits, the multiplicand register is 37 bits and the accumulator is 45 bits in length. The output is truncated to 16 bits.

As an example, consider two cascaded low pass filters used to decimate an input sample rate by a factor of four and present a clean, anti-aliased output to a follow-on operation.

The first filter is a 27-tap low pass with a decimation of two, and the second is a 63-tap low pass, also with a decimation of two. The input sample rate is 200,000 samples per second and the output is 50,000 samples per second. Note that the filter block will work for any sample rates for which each output sample can be computed in the time between input samples. For very high sample rates, additional add, multiply and accumulate functions can be added, and the memories can be interleaved by additional factors to improve memory bandwidth.

For the example, the 27-tap filter is allocated storage memory addresses from 0 to 26, and the 63-tap filter is allocated addresses 28 through 90. The first filter's coefficients are loaded into addresses 0 through 13 of the coefficient memory (105) and the second filters tap weights are stored into locations 14 through 45. The master controller (190) maintains the current state for each filter, and swaps control to perform one filter followed by another with appropriate decimation. A decimation of two indicates that only every other output sample is calculated, and output, for each input sample.

We claim:

1. An integrated circuit for implementing a digital filter; the integrated circuit: comprising:
a data memory; the data memory having first and second ports to permit the access of two data samples at the same time;
A coefficient memory for storing filter coefficients;
a first adder for adding data samples read from the first and second ports;
A multiplier for multiplying a value from the first adder by a value read from the coefficient memory;
a second adder for accumulating values from the multiplier; and,
a master controller; the master controller being configured for selectively storing the accumulated values in the data memory for further processing or outputting the accumulated values.

2. The integrated circuit of claim 1, where the data memory and the coefficient memory are random-access memory.

3. The integrated circuit of claim 1, further comprising an address and control block for holding values appropriate to the filter to be executed; the address and control block in communication with the data memory and the coefficient memory.

4. The integrated circuit of claim 3, where the address and control block further comprises a first set of registers for holding values for a first pre-determined digital filter, and a second set of registers holding corresponding values for a second pre-determined digital filter.

5. The integrated circuit of claim 4, where the first set of registers comprises at least:
a write address register holding the address of the next input data to, selectively, data memory or coefficient memory;
a first read address register holding the address of the next data to be read from the first port of the data memory;
a second read address register holding the address of the next data to be read from the second port of the data memory; and,
a coefficient address register holding the address of the next coefficient to be read.

6. The integrated circuit of claim 1, further comprising a master controller; the master controller having a computer readable medium containing instructions to implement a pre-determined digital filter.

7. A method for implementing a digital filter, the method comprising:
providing a data memory and a coefficient memory; the data memory comprising first and second ports;
further providing an address and control block; the address and control block holding a first set of parameters for controlling the operation of the digital filter;
maintaining a current write address for data in the address control block as a circular list; the circular list having a size equal to a predetermined number of filter taps;
maintaining a first read address for data to be read from the first data memory port as a first-in-first-out queue;
maintaining a second read address for data to be read from the second data memory port as a last-in-first-out stack;
maintaining a coefficient read address as a circular list, the coefficient address having a size equal to the pre-determined number of filter taps divided by 2 and rounded up if the number of filter taps is odd;
storing an input digital sample in the data memory, at a location determined by a current write address in the address control block; and, computing an output sample from the stored samples in the data memory and the stored coefficients in the coefficient memory.

8. The method of claim 7, further comprising the step of storing the computed output sample in the data memory.

9. The method of claim 7, further comprising:
maintaining a decimation counter in the address control block;
for each input sample, decrementing the decimation counter until the decimation counter is zero before computing the output sample.

10. The method of claim 7, where the first and second read addresses, the write address, and the coefficient address are maintained as virtual memory addresses in the respective memories.

11. A method for implementing a cascaded digital filter, the method comprising:
providing a data memory and a coefficient memory; the data memory comprising first and second memory ports;
further providing an address and control block; the address and control block holding a first set of parameters for controlling the operation of a first digital filter; further providing a second set of control parameters in the address control block; the second set of parameters holding values for controlling operation of a second digital filter;
maintaining a current write address for data in the address control block as a circular list; the circular list having a size equal to a predetermined number of filter taps;
maintaining a first read address for data to be read from the first data memory port as a first-in-first-out queue;
maintaining a second read address for data to be read from the second data memory port as a last-in-first-out stack;
maintaining a coefficient read address as a circular list, the coefficient address having a size equal to the pre-determined number of filter taps divided by 2 and rounded up if the number of filter taps is odd;
storing an input digital sample in the data memory, at a location determined by a current write address in the address control block;
computing an output sample for the first digital filter from the stored samples in the data memory and the stored coefficients in the coefficient memory;
exchanging the first set of parameters in the address control block with the second set of parameters in the address control block;
computing an output sample for the cascaded digital filter from the stored samples in the data memory and the stored coefficients in the coefficients in the coefficient memory; and,
exchanging the first set of parameters in the address control block with the second set of parameters in the address control block.

12. The method of claim 10, further comprising the step of storing the computed output sample in the data memory.

13. The method of claim 10, further comprising:
maintaining a decimation counter in the address control block;
for each input sample, decrementing the decimation counter until the decimation counter is zero before computing the output sample.

14. The method of claim 10, where the first and second read addresses, the write address, and the coefficient address are maintained as virtual memory addresses in the respective memories.

15. A computer-readable medium having computer-executable instructions for performing a method for implementing a digital filter in an apparatus comprising: a data memory and a coefficient memory; the data memory comprising first and second memory ports; and, an address and control block; the address and control block holding a first set of parameters for controlling the operation of the digital filter; the method comprising:
maintaining a current write address for data in the address control block as a circular list; the circular list having a size equal to a predetermined number of filter taps;
maintaining a first read address for data to be read from the first data memory port as a first-in-first-out queue;
maintaining a second read address for data to be read from the second data memory port as a last-in-first-out stack;
maintaining a coefficient read address as a circular list, the coefficient address having a size equal to the predetermined number of filter taps divided by 2 and rounded up if the number of filter taps is odd;
storing an input digital sample in the data memory, at a location determined by a current write address in the address control block; and,
computing an output sample from the stored samples in the data memory and the stored coefficients in the coefficient memory.

16. The computer-readable medium of claim 15, where the method further comprises the step of storing the computed output sample in the data memory.

17. The computer-readable medium of claim 15, where the method further comprises:
maintaining a decimation counter in the address control block;
for each input sample, decrementing the decimation counter until the decimation counter is zero before computing the output sample.

18. The computer-readable medium of claim 15, where the first and second read addresses, the write address, and the coefficient address are maintained as virtual memory addresses in the respective memories.

19. A computer-readable medium having computer-executable instructions for performing a method for implementing a cascaded digital filter in an apparatus comprising:
a data memory and a coefficient memory; the data memory comprising first and second memory ports; an address and control block; the address and control block holding a first set of parameters for controlling the operation of a first digital filter; and, a second set of control parameters in the address control block; the second set of parameters holding values for controlling operation of a second digital filter; the method comprising:
maintaining a current write address for data in the address control block as a circular list; the circular list having a size equal to a predetermined number of filter taps;
maintaining a first read address for data to be read from the first data memory port as a first-in-first-out queue;
maintaining a second read address for data to be read from the second data memory port as a last-in-first-out stack;
maintaining a coefficient read address as a circular list, the coefficient address having a size equal to the pre-determined number of filter taps divided by 2 and rounded up if the number of filter taps is odd;
storing an input digital sample in the data memory, at a location determined by a current write address in the address control block;
computing an output sample for the first digital filter from the stored samples in the data memory and the stored coefficients in the coefficient memory;
exchanging the first set of parameters in the address control block with the second set of parameters in the address control block;
computing an output sample for the cascaded digital filter from the stored samples in the data memory and the stored coefficients in the coefficients in the coefficient memory; and,
exchanging the first set of parameters in the address control block with the second set of parameters in the address control block.

20. The computer-readable medium of claim 19, where the method further comprises the step of storing the computed output sample in the data memory.

21. The computer-readable medium of claim 19, where the method further comprises:
maintaining a decimation counter in the address control block;
for each input sample, decrementing the decimation counter until the decimation counter is zero before computing the output sample.

22. The computer-readable medium of claim 19, where the first and second read addresses, the write address, and the coefficient address are maintained as virtual memory addresses in the respective memories.
